(19) United States
(12) Patent Application Publication
(10) Pub. No.: US 2016/0132163 A1
(43) Pub. Date: May 12, 2016

(54) TOUCH MODULE AND MOBILE TERMINAL

(71) Applicant: Shenzhen China Star Optoelectronics Technology Co. Ltd., Shenzhen, Guangdong (CN)

(72) Inventors: Jie Qiu, Shenzhen (CN); Yung-lun Lin, Shenzhen (CN); Ruhai Fu, Shenzhen (CN); Chengliang Ye, Shenzhen (CN); Chun-kai Chang, Shenzhen (CN)

(73) Assignee: Shenzhen China Star Optoelectronics Technology Co. Ltd., Shenzhen, Guangdong (CN)

(21) Appl. No.: 14/407,648

(22) PCT Filed: Nov. 20, 2014
(86) PCT No.: PCT/CN2014/091773

§ 371 Date: Dec. 12, 2014

(30) Foreign Application Priority Data
Nov. 6, 2014 (CN) 2014106215740

(51) Int. Cl. G06F 3/041; G02B 27/22; H01L 31/054

(52) U.S. Cl. CPC G06F 3/0412; H01L 31/0543; G02B 27/2228

(57) ABSTRACT

A touch module includes a touch panel, a solar panel and a grating lens. The solar panel is disposed under the touch panel, and includes a light receiving area that faces towards the touch panel. The grating lens is disposed between the solar panel and the touch panel, the grating lens presents a first lens effect under a first control mode, and introduces external light passing through the touch panel and irradiated on the grating lens to the light receiving area of the solar panel under the first control mode. The present invention also discloses a mobile terminal that includes the above touch module. Through the above manners, the present invention stacks the solar panel and the touch panel together, and utilizes the lens effect of grating lens to converge external light thereby efficiently reducing non-display area of touch module and improving the photoelectric conversion efficiency.

### TECHNICAL FIELD

The present invention relates to mobile terminals, and more particularly to a touch module and a mobile terminal.

### BACKGROUND

Currently, mobile terminals are usually powered by chemical batteries, such as Li-ion batteries, nickel cadmium batteries, and etc. These chemical batteries can only provide limited power. However, with the development of hardware and software of mobile terminals, energy required by mobile terminals is also becoming more and more. At the same time, recharging of mobile terminals can only be achieved when there are both the recharging power source and recharging equipment. Thus, lack of endurance and cannot charge anywhere have become a major problem of mobile terminals nowadays.

It was proposed to use solar cells in mobile terminals. However, it is required to integrate solar cell in a mobile terminal, and ensure that external light can be irradiated onto the solar cell at the same time. FIG. 1 illustrates a typical configuration. A mobile terminal 102 in FIG. 1 includes a surface, and solar panel 104, a display screen 106 and a keyboard 108 disposed on the surface. The solar panel 104 is used to receive external light beams and converts the solar energy to electrical energy. The area of the solar panel 104 determines the amount of received external light, and in other words, determines the magnitude of power outputted.

However, touch panel are commonly used in mobile terminals, resulting in non-display area, which can be used to dispose solar panel, of outer surface mobile terminals become smaller and smaller, thus there is the problem of insufficient light can be obtained, and the solar panel provide on an outer surface of a mobile terminal also cause the problems of bad external appearance and poor user experience.

### SUMMARY

A primary problem solved by embodiments of the present invention is to provide a touch module and a mobile terminal, which are capable of efficiently reducing the area of non-display area of touch module and significantly improving the photoelectric conversion efficiency of the solar panels, by stacking a solar panel and a touch panel together and introduce external light to the solar panel using the lenticular effect of grating lens.

To solve the above problem, the embodiments of the present invention provide a touch module, which includes a touch panel, a solar panel, and a grating lens.

The solar panel is disposed under the touch panel, and the solar panel includes a light receiving area that faces towards the touch panel. The grating lens is disposed between the solar panel and the touch panel, the grating lens presents a first lens effect under a first control mode, and introduces external light passing through the touch panel and irradiated on the grating lens to the light receiving area of the solar panel under the first control mode.

In one embodiment, the touch module further includes a display panel disposed under the solar panel; the grating lens presents a second lens effect under a second control mode and introduces three dimensional images of left eye and right eye to the left eye and right eye of the users, respectively, under the second control mode.

In one embodiment, the grating lens presents a non-lens characteristic of uniform refracting indexes under a third control mode, and the grating lens introduces 2D images displayed by the display panel to the users' eyes directly.

In one embodiment, the display panel includes a transparent area and an opaque area, and the light receiving area of the solar panel is overlapped with the opaque area of the display panel.

In one embodiment, the opaque area is at least one of a data line area, a scanning line area, a black matrix area and a border area.

To solve the above problem, the embodiments of the present invention provide a touch module, which includes a touch panel, a display panel, and a grating lens.

The display panel is disposed under the touch panel, the display panel includes a transparent area and an opaque area, the opaque area is capable of converting irradiated solar energy to electrical energy. The grating lens is disposed between the display panel and the touch panel, the grating lens presents a first lens effect under a first control mode, and introduces external light passing through the touch panel and irradiated onto the grating lens to the light receiving area of the solar panel under the first control mode.

In one embodiment, the grating lens presents a second lens effect under a second control mode and introduces three dimensional images of left eye and right eye to the left eye and right eye of the users, respectively, under the second control mode.

In one embodiment, the grating lens presents a non-lens characteristic of uniform refracting indexes under a third control mode, and the grating lens introduces 2D images displayed by the display panel to the users' eyes directly.

In one embodiment, the opaque area is at least one of a data line area, a scanning line area, a black matrix area and a border area.

To solve the above problem, the embodiments of the present invention provide a mobile terminal. The mobile terminal includes a touch module, which includes a touch panel, a solar panel, and a grating lens.

The solar panel is disposed under the touch panel, and the solar panel includes a light receiving area that faces towards the touch panel. The grating lens is disposed between the solar panel and the touch panel, the grating lens presents a first lens effect under a first control mode, and introduces external light passing through the touch panel and irradiated on the grating lens to the light receiving area of the solar panel under the first control mode.

In one embodiment, the touch module further includes a display panel, disposed under the solar panel; the grating lens presents a second lens effect under a second control mode and introduces three dimensional images of left eye and right eye to the left eye and right eye of the users, respectively, under the second control mode.

In one embodiment, the grating lens presents a non-lens characteristic of uniform refracting indexes under a third control mode, and the grating lens introduces 2D images displayed by the display panel to the users' eyes directly.

In one embodiment, the display panel includes a transparent area and an opaque area, and the light receiving area of the solar panel is overlapped with the opaque area of the display panel.

In one embodiment, the opaque area is at least one of a data line area, a scanning line area, a black matrix area and a border area.

The advantages of the above embodiments are described as follows. Differing from the existing art, in the above embodiments, the solar panel and the touch panel is stacked together. The grating lens is employed to converge external light using the lens effect of the grating lens. The grating lens introduces the external light to the solar panel. The area of the non-display area of the touch module is efficiently reduced, and the photoelectric conversion efficiency is significantly improved.

### BRIEF DESCRIPTION OF THE DRAWINGS

FIG. 1 is a schematic view of a mobile terminal with a solar panel in the related art.

FIG. 2 is a schematic view of a first embodiment of the touch module.

FIG. 3 is a schematic optical path diagram of a first control mode of the touch module in FIG. 2.

FIG. 4 is a schematic view of a second embodiment of the touch module.

FIG. 5a is a schematic optical path diagram of a second control mode of the touch module in FIG. 4.

FIG. 5b is a schematic optical path diagram of a third control mode of the touch module in FIG. 4.

FIG. 6 is a schematic view of a display panel of a touch module in accordance with embodiments of the present invention.

FIG. 7 is a schematic view of a third embodiment of the touch module.

FIG. 8 is a schematic view of a mobile terminal in accordance with a fourth embodiment.

FIG. 9 is a flow chart of selecting the three control modes.

FIG. 10 is a flow chart of battery managing in the mobile terminal of the FIG. 8.

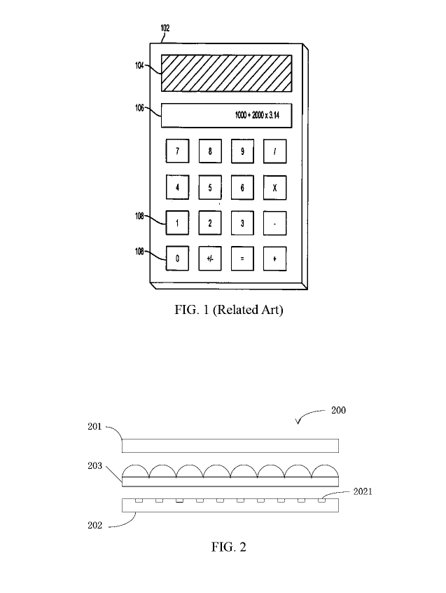

### DETAILED DESCRIPTION OF PREFERRED EMBODIMENTS

Please referrers to FIG. 2; FIG. 2 is a schematic view of a first embodiment of the touch module. The first embodiment provides a touch module 200, which includes a touch panel 201, a solar panel 202 and a grating lens 203.

In the present embodiment, the touch panel 201 can be any touch panel. Generally, the touch panel 201 is a square, flat and non-hollowed structure. Taking a capacitive touch panel as an example, the touch panel 201 includes a glass substrate, a conductive layer, an electrode layer and a protective layer. The touch sensing is achieved by the following procedure; a voltage is applied to the touch panel 202 to produce a constant electrical field. When a finger touches the touch panel 201, the static electricity from the finger is conducted to the electrode layer and causes variation of the capacity at the touch point. Accordingly, the current is also varied. According to the rate of current changing, the position of the touch point can be calculated. The touch panel 201 can be a single layer glass substrate and has a light transmittance rate of 90%.

In other embodiments, the touch panel 201 can be made into different shapes according to practical applications. For example, the touch panel 201 can be circular when used in a sport watch; can be a combination of multiple shapes, such as a combination of square and diamond shape, when used in smart home devices. The touch panel 201 can also be a hollowed structure with certain patterns. The touch panel 201 can be made of flexible materials, and then the touch panel 201 can be a curved touch panel. Besides, the touch panel 201 can also be a resistance type, an optical type or an acoustic type touch panel. The touch panel 201 can also be a combination of multiple types to achieve different touch sensing manners.

The solar panel 202 is disposed below the touch panel 201. The solar panel 202 further includes a light receiving area 2021, and the light receiving area 2021 is facing towards the touch panel 201.

In the present embodiment, the touch panel 201 covers the solar panel 202 entirely, and the light receiving area 2021, which is located on a surface of the solar panel 202, is facing towards the touch panel 201. The solar panel 202 is electrically connected to the touch panel 201 using a flexible ribbon cable for providing electrical power to the touch panel 201. In the present embodiment, the solar panel 202 can be a thin film solar panel, and is flexible. The solar panel 202 can be made into a planar or non-planar structure of different shapes. The solar panel 202 is usually attached to other elements, and then the shape of the solar panel 202 can be mated with the other elements. Thus, the shape of the solar panel 202 is not limited in the present embodiment.

In other embodiments, the solar panel can also be disposed under the touch panel 201, and is partially covered by the touch panel 201. The solar panel 202 and the touch panel 201 can also be disconnected. Then the touch panel 201 can be powered by other chemical batteries. When the touch panel 201 and the solar panel 202 are flexible, direct connection between them can be achieved and the flexible is not necessary then.

The grating lens 203 is disposed between the solar panel 22 and the touch panel 201. The grating lens 203 presents a first focusing effect at a first control mode, which introduces the light that passes through the touch panel 201 and irradiated on the grating lens 203 to the light receiving area 2021.

In the present embodiment, the grating lens 203 is preferably an adjustable liquid crystal lens, which includes an upper substrate, a bottom substrate, and a liquid crystal layer sealed in the upper substrate and the bottom substrate. An electrode is disposed on at least one of the upper substrate and the bottom substrate. By applying a voltage onto the electrode, an electrical filed of a predetermined shape is provided. The electric field aligns liquid crystal molecular in the liquid crystal layer along the direction of the electrical field. Then, the liquid crystal layer presents the characteristic of a lens. The position and focal length of the liquid crystal lenticular lens can be varied by adjusting the electric field.

In the present embodiment, the grating lens 203 is disposed between the solar panel 202 and the touch panel 201. The grating lens 203 includes a number of parallel lens units 2031. A distance between the grating lens 203 and the solar panel 202 is preferably the focal length of the lens units 2031.

Please referrers to FIG. 3, FIG. 3 is a schematic view how the light is transmitted under the first control mode. According to the first control mode, external light passing through the touch panel 201 enters the grating lens 203. Usually, the external light is regarded as parallel light, and thus the external light is focused on a focal point after passing through the grating lens. That is, the light is converged into the light receiving area 2021.

In other embodiments, the grating lens 203 can be comprised of different cylindrical lens units 2031, and each lens unit 2031 can have different focal length. Under such condition, the solar panel 202 can be a flexible three-dimensional structure corresponding to the cylindrical lens units 2031 to ensure that light passing through each cylindrical lens unit 2031 can be converged to the light receiving area 2021 of the solar panel 202.

Differing form the existing art, the present embodiment stacks the solar panel and the touch panel together, and introduces external light to the light receiving area of the solar panel using the grating lens, and thus the solar panel can receive more light and produce more electrical energy.

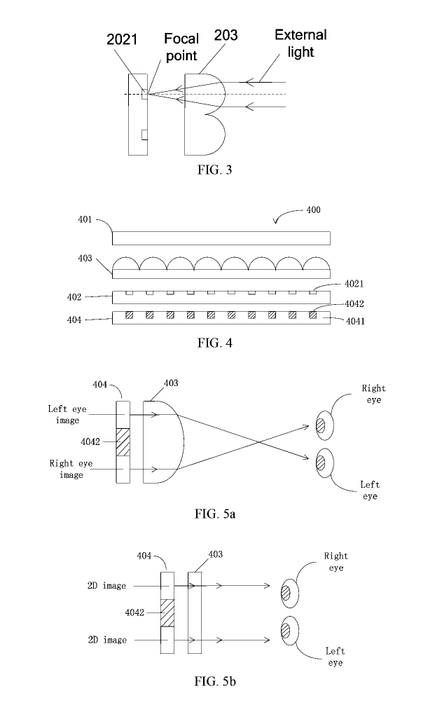

Referring to FIG. 4, FIG. 4 is a schematic view of a second embodiment of the touch module of the present invention. The present embodiment provides a touch module 400, which includes a touch panel 401, a solar panel 402, grating lens 403 and a display panel 404.

The solar panel 402 is disposed beneath the touch panel 401. The solar panel 402 further includes a light receiving area 4021, and the light receiving area 4021 is facing towards the touch panel 401.

The grating lens 403 is disposed between the solar panel 402 and the touch panel 401. The grating lens 403 presents a first lens effect under the first control mode, which introduces external light passing through the touch panel 401 and irradiated on the grating lens 403 to the light receiving area 4021.

In the present embodiment, other elements of the touch panel 401, the solar panel 402 and the grating lens 403 can be referred back to the first embodiment.

In the present embodiment, the solar panel 404 is beneath the solar panel 402. The grating lens 403 presents a second lens effect under a second control mode, which introduces 3D images of left eye and right eye displayed by the display panel 404 to left eye and right eye of the user, respectively. Under a third control mode, the grating lens 403 has uniform refracting indexes, in other words, the grating lens is not a lens then. Thus, the images displayed by the display panel 404 pass through the grating lens 403 directly and enter into eyes of the user. The display panel 404 includes a transparent area 4041 and opaque area 4042.

In the present embodiment, the grating lens 403 presents three different lenses effects under three control modes. Under the first control mode, external light passes through the touch panel 401 and enters into the grating lens 403, and then is converged to the light receiving area 4021 by the grating lens 403.

Under the second control mode, the display panel 404 divides a 3D image into a left eye image and a right eye image. The grating lens 403 is a cylindrical lens grating and is comprised of a number of identical cylindrical lenses. Referring to FIG. 5a, FIG. 5a is a schematic view how the light is transmitted under the second control mode. Under the second control mode, 3D images of left eye and right eye displayed by the display panel 404 pass through grating lens 403, and then are introduced to left eye and right eye of the user, respectively. Eyes of the user receive images of different parallax images, and a stereoscopic image has three dimensional effect is produced by the user's brain.

Under the third control mode, the grating lens 403 has uniform refracting indexes, in other words, the grating lens is not a lens then. Thus, the images displayed by the display panel 404 pass the grating lens 403 directly and enter into eyes of the user. Thus, the two dimensional display is achieved. Referring to FIG. 5b, FIG. 5b is a schematic optical path diagram of the third control mode. The lens effects presented under the second control mode and the third control mode are achieved by the combination of the grating lens 403 and the display panel 403. When the user want to display three dimension (3D) images, the display panel 404 will receive 3D image data and display the 3D images. The displayed images pass the grating lens and enter into the user's eyes and present the 3D effect. When the user want to display two dimensional (2D) images, the display panel 404 will receive image data of 2D effect and display the 2D image. The displayed 2D image also passes through the grating lens 403 and enters into the user's eyes.

In other embodiments, more lenses mode can be achieved by adjusting the grating lens. When the grating lens 403 is a cylindrical grating lens, mounting angles thereof can be adjusted to change the light incident angle thereby change the display effect.

In other embodiments, there is a transparent area 4041 and an opaque area 4042 disposed on the display panel 404. The light receiving area 4021 of the solar panel 402 is overlapped with the opaque area 4042 of the display panel 404.

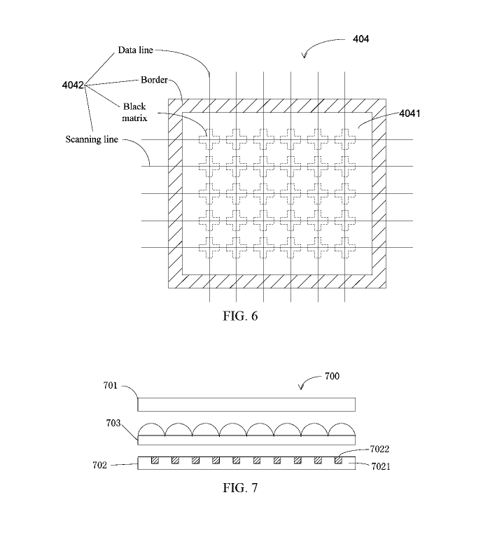

When the display panel 404 works, the second control mode and the third control mode can be selected, and then the light emitted by the display panel 404 is not affected by the solar panel 402. When the display panel 404 is shut down, the first control mode can be switched on. Then, the external light can be converged to the light receiving area 4021 of the solar panel 402, and thus the solar energy is converted into electrical energy and stored. The position of the light receiving area 4021 of the solar panel 402 can be determined according to the position of the opaque area 4042 of the display panel 404. The opaque area 4042 of the display panel 404 usually includes a data line area, scanning line area, black matrix area, and a border area. Thus, the light receiving area 4021 can be optionally disposed on one or more of the areas. The detail configuration can be referred to FIG. 6, which is a schematic view of the structure of the display panel.

Differing from the existing art, the present embodiment utilizes the grating lens to introduce the external light to the light receiving area such the solar panel can receive more light and produce more electrical energy then. In addition, the grating lens can work under three control modes and presents three different lens effects. Thus, the grating lens achieves three different functions of introducing light to the solar panel, displaying 3D images and display 2D images according to requirements of the users.

Referring to FIG. 7, FIG. 7 is a schematic view of a third embodiment of the touch module of the present invention. The present embodiment provides a touch module 700, which includes a touch panel 701, a display panel 702 and grating lens 703.

The display panel 702 is disposed under the touch panel 701, and there is a transparent area 7021 and an opaque area 7022 disposed on the display panel 7-2. The opaque area 702 can converts incident light into electrical energy.

The opaque area 7022 of the display panel 702 has the functionality of converting light into electrical energy. In the present embodiment, a thin film solar panel is fixed in the opaque are 7022 of the display panel 702 using sticking, latching, nesting or any other fixing means. The selected thin film solar panel has a thickness of 0.1˜1 um. The thin film solar panel is also flexible, and is capable of being tightly stuck to a planar or 3D structure as a portion of the display panel 702. The opaque area 7022 of the display panel 702 mainly includes the data line area, the scanning line area, the black matrix area, and the border area.

In other embodiments, photoelectric materials can be used to make the opaque area 7022 of the display panel 702. Then, the opaque are 7022 can converts light into electrical energy. The photoelectric materials, for example, can be crystalline silicon, amorphous silicon or multiple compounds.

The grating lens 703 is disposed between the display panel 702 and the touch panel 701, and can presents three different lens effects under three control modes. These three different lens effects can be used to achieve three different functions. Under a first control mode, the grating lens 703 presents a first lens effect, which introduces light passing through the touch panel 701 and entering the grating lens 703 to the opaque area 7022. Under a second control mode, the grating lens 703 presents a second lens effect, which introduces 3D images of left eye and right eye displayed by the transparent area 7021 of the display panel 702 to left eye and right eye of the user, respectively. Under a third control mode, the grating lens 703 presents a non-lens effect, which allows the 2D image displayed by the transparent area 7021 of the display panel 702 to pass through and enters the user's eyes.

The above three control modes are similar to that described in the second embodiment.

Differing from the existing art, the display panel of the present embodiment coverts light to electrical energy. Compared to other embodiments, the solar panel is reduced and thus the structure is more compact, and this is helpful for the flat thin design of mobile terminals. In addition, similar to the second embodiment, the grating lens can present three different lens effects under three different control modes. Thus, the grating lens achieves three different functions of introducing light to the solar panel, displaying 3D images and display 2D images according to requirements of the users.

Referring to FIG. 8, FIG. 8 is a schematic view of a mobile terminal in accordance with a fourth embodiment. The present embodiment provides a mobile terminal 800, which includes a touch panel 801, a solar panel 802, grating lens 803, a display panel 804, a chemical battery 805 and a processor 806.

The solar panel 802 is disposed under the touch panel 801. The solar panel 802 further includes a light receiving are 8021, and the light receiving area 8021 is facing towards the touch panel 801.

The grating lens 803 is disposed between the solar panel 802 and the touch panel 801. The grating lens 803 presents a first lens effect under a first control mode, which introduces the light passing through the touch panel 801 and irradiated on the grating lens 803 to the light receiving area 8021.

The display panel 804 is disposed under the solar panel 802. The grating lens 803 presents a second lens effect, which introduces 3D images of left eye and right eye displayed by the display panel 804 to left eye and right eye of the user, respectively. The grating lens 803 presents a non-lens effect, which allows the 2D image displayed by the display panel 804 to pass through and enters into the user's eyes.

The display panel 804 further includes a transparent area and an opaque area. The light receiving area 8021 of the solar panel 802 may include multiple areas spaced apart from each other. In addition, the light receiving area 8021 of the solar panel 802 can be overlapped with the opaque area of the display panel 804.

In the present embodiment, the touch panel 801, the solar panel 802, the grating lens 803, and the display panel 804 are similar to those described in the second embodiment.

The chemical battery 805 is configured for supplying power to the mobile terminal 800.

In the present embodiment, the chemical battery 805 is a Li-ion battery, and can also be a lead acid battery, a nickel cadmium battery, a nickel iron battery, a nickel hydrogen battery, etc.

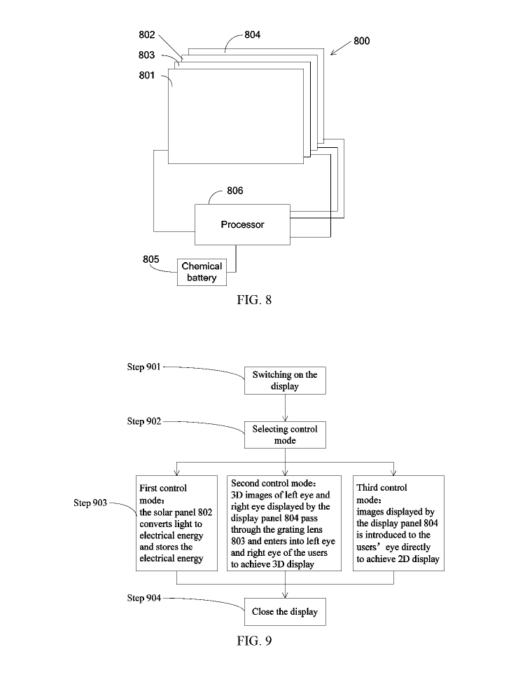

The processor 806 is connected to the touch panel 801, the solar panel 802, the grating lens 803, the display panel 804 and the chemical battery 805. The processor is configured for controlling the selection of the three control modes. Referring to FIG. 9, FIG. 9 is a flow chart of the selection of the three control modes. The flow includes the following steps.

Step 901, the display is switched on.

Step 902, the control mode is selected.

Step 903, if the first control mode is selected, the solar panel 802 converts the light energy to electrical energy, and stores the electrical energy. If the second control mode is selected, then the 3D images of left eye and right displayed by the display panel 804 are introduced by the grating lens 803 to the left eye and right eye of the user, respectively, to achieve 3D display. If the third control mode is selected, 2D images displayed by the display panel 804 is directly introduced to the users' eyes to achieve 2D display.

Step 904, the display is finished.

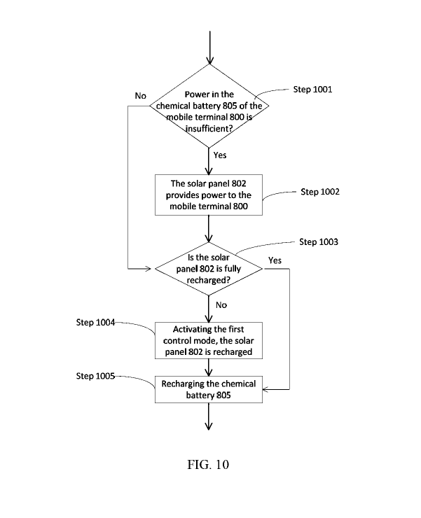

The processor 806 is further configured for managing the power usage of the solar panel 802 and the chemical battery 805. The mobile terminal 800 is mainly powered by the chemical battery 805. When the chemical battery 805 has insufficient power, then the mobile terminal 800 can be powered by the solar panel 802. Referring to FIG. 10, FIG. 10 is a flow chart of managing the power usage of the mobile terminal in accordance with the fourth embodiment. The flow includes the following steps.

Step 1001, it is judged that whether there is sufficient power in the chemical battery 805 of the mobile terminal 800. If the power is sufficient, then a step 1003 is executed; otherwise, a step 1002 is executed.

Step 1002, the solar panel 802 supply electrical power for the mobile terminal 800.

Step 1003, it is judged that whether the solar panel 802 is fully recharged. If the solar panel 802 is fully recharged, then a step 1005 is executed; otherwise a step 1004 is executed.

Step 1004, the first control mode is activated and the solar panel 802 is recharged.

Step 1005, the chemical battery 805 is recharged. In this step, two recharging modes can be used, one is to recharge the chemical battery 805 using the solar panel 802, and the other one is to recharge the chemical battery 805 using common rechargers connected to power source.

In other embodiments, the chemical battery 805 can also not be included in the mobile terminal 800. Then, the mobile terminal 800 is only powered by the chemical battery 802. Accordingly, the flow of managing the power usage can also be achieved by other manners.

Differing from the existing art, the present embodiment uses the touch panel in a mobile terminal, and thus the solar panel can supply electrical power to the mobile terminal. In addition, the mobile terminal can also achieve 3D display and 2D display. Besides, a flow of battery managing is established in the mobile terminal, the mobile terminal is mainly powered by the chemical battery and the solar panel is used as an auxiliary power source, resulting in adequate power of the mobile terminal anytime.

The above description is only embodiment of the present invention, and is not used to limit the scope of the present invention. Any equivalent structure or equivalent flow alternatives made from the specification and figures of the present invention, or direct or indirect application of the present invention into other related fields, should be included in the scope of the present invention.

What is claimed is:

1. A touch module, comprising:
a touch panel;
a solar panel, disposed under the touch panel, and the solar panel comprising a light receiving area that faces towards the touch panel;
a grating lens, disposed between the solar panel and the touch panel, the grating lens presenting a first lens effect under a first control mode, and introducing external light passing through the touch panel and irradiated on the grating lens to the light receiving area of the solar panel under the first control mode.

2. The touch module of claim 1, wherein the touch module further comprises a display panel, disposed under the solar panel, the grating lens presenting a second lens effect under a second control mode and introducing three dimensional images of left eye and right eye to the left eye and right eye of the users, respectively, under the second control mode.

3. The touch module of claim 2, wherein the grating lens presents a non-lens characteristic of uniform refracting indexes under a third control mode, and the grating lens introduces 2D images displayed by the display panel to the users' eyes directly.

4. The touch module of claim 1, wherein the display panel comprises a transparent area and an opaque area, and the light receiving area of the solar panel is overlapped with the opaque area of the display panel.

5. The touch module of claim 4, wherein the opaque area is at least one of a data line area, a scanning line area, a black matrix area and a border area.

6. A touch module, comprising:
a touch panel;
a display panel, disposed under the touch panel, the display panel comprising a transparent area and an opaque area, the opaque area being capable of converting irradiated solar energy to electrical energy;
a grating lens, disposed between the display panel and the touch panel, the grating lens presenting a first lens effect under a first control mode, and introducing external light passing through the touch panel and irradiated onto the grating lens to the light receiving area of the solar panel under the first control mode.

7. The touch module of claim 6, wherein the grating lens presents a second lens effect under a second control mode and introduces three dimensional images of left eye and right eye to the left eye and right eye of the users, respectively, under the second control mode.

8. The touch module of claim 6, wherein the grating lens presents a non-lens characteristic of uniform refracting indexes under a third control mode, and the grating lens introduces 2D images displayed by the display panel to the users' eyes directly.

9. The touch module of claim 6, wherein the opaque area is at least one of a data line area, a scanning line area, a black matrix area and a border area.

10. A mobile terminal, comprising a touch module, the touch module comprising:
a touch panel;
a solar panel, disposed under the touch panel, and the solar panel comprising a light receiving area that faces towards the touch panel;
a grating lens, disposed between the solar panel and the touch panel, the grating lens presenting a first lens effect under a first control mode, and introducing external light passing through the touch panel and irradiated on the grating lens to the light receiving area of the solar panel under the first control mode.

11. The mobile terminal of claim 10, wherein the touch module further comprises a display panel, disposed under the solar panel, the grating lens presenting a second lens effect under a second control mode and introducing three dimensional images of left eye and right eye to the left eye and right eye of the users, respectively, under the second control mode.

12. The mobile terminal of claim 11, wherein the grating lens presents a non-lens characteristic of uniform refracting indexes under a third control mode, and the grating lens introduces 2D images displayed by the display panel to the users' eyes directly.

13. The touch module of claim 10, wherein the display panel comprises a transparent area and an opaque area, and the light receiving area of the solar panel is overlapped with the opaque area of the display panel.

14. The touch module of claim 4, wherein the opaque area is at least one of a data line area, a scanning line area, a black matrix area and a border area.
